(19) United States
(12) Patent Application Publication
(10) Pub. No.: US 2025/0248249 A1
(43) Pub. Date: Jul. 31, 2025

(54) DISPLAY DEVICE AND METHOD OF FORMING THE SAME

(71) Applicant: LG Display Co., Ltd., Seoul (KR)

(72) Inventors: Bokyoung LEE, Paju-si (KR); SeungHee NAM, Paju-si (KR); SeokWoo SON, Paju-si (KR)

(21) Appl. No.: 18/917,596

(22) Filed: Oct. 16, 2024

(30) Foreign Application Priority Data
Jan. 31, 2024 (KR) 10-2024-0015199

(51) Int. Cl. H10K 59/131; H10K 59/121; H10K 59/124

(52) U.S. Cl. CPC H10K 59/131; H10K 59/1213; H10K 59/124

(57) ABSTRACT

Embodiments of the present disclosure relates to a display device and a method of manufacturing the same. A display device may include a substrate including a first area and a second area, a buffer layer on the substrate, a first semiconductor pattern disposed in the first area and on the buffer layer, a second semiconductor pattern disposed in the second area and on the buffer layer, a first gate insulating layer disposed on the first semiconductor pattern in a portion of the first area, and covering at least a portion of an upper surface of the first semiconductor pattern, and a second gate insulating layer disposed on the first gate insulating layer, the second semiconductor pattern, and the buffer layer. According to embodiments of the present disclosure, it is possible to prevent an interface contamination which may occur when disposing a driving circuit for driving the display panel.

### CROSS-REFERENCE TO RELATED APPLICATION

This application claims priority from Korean Patent Application No. 10-2024-0015199, filed on Jan. 31, 2024, which is hereby incorporated by reference for all purposes as if fully set forth herein.

### BACKGROUND

### Technical Field

The present disclosure relates to a display device and a method of manufacturing the same.

### Description of the Related Art

As the information society develops, a display device for displaying images is required to be lighter and thinner. The display device may further include a driving circuit for driving a display panel around the display panel in addition to the display panel implementing the image. As display devices become lighter and thinner, there may be a case in which the driving circuits are disposed within a portion of the display panel.

However, during the process of arranging the driving circuits for driving the display panel within the display panel, the contamination may occur at the interface between components within the panel at the location where the driving circuit is placed, which may cause a decrease in the reliability of the display device.

In addition, due to various buffer layers disposed together when the driving circuit is placed in the display panel, the current characteristics of the device for providing an image display function may deteriorate, which may cause luminance defects in the display device, and may limit the process freedom of other components in the display panel.

### BRIEF SUMMARY

Embodiments of the present disclosure may provide a display device and a method of manufacturing the same capable of preventing interface contamination which may occur when disposing the driving circuits for driving a display panel.

Embodiments of the present disclosure may provide a display device and a method of manufacturing the same capable of preventing luminance defects of the display device when disposing the driving circuits for driving the display panel.

Embodiments of the present disclosure may provide a display device and a method of manufacturing the same capable of securing a process freedom of other components in the display panel when disposing the driving circuits for driving the display panel.

Embodiments of the present disclosure may provide a display device including a substrate including a first area and a second area, a buffer layer on the substrate, a first semiconductor pattern disposed in the first area and on the buffer layer, a second semiconductor pattern disposed in the second area and on the buffer layer, a first gate insulating layer on the first semiconductor pattern in a portion of the first area, and covering at least a portion of an upper surface of the first semiconductor pattern, and a second gate insulating layer on the first gate insulating layer, the second semiconductor pattern, and the buffer layer.

Embodiments of the present disclosure may provide a display device including a substrate including a first area and a second area, a first transistor disposed in the first area and including a first semiconductor pattern, a first gate electrode, a first source electrode, and a first drain electrode, a second transistor disposed in the second area and including a second semiconductor pattern, a second gate electrode, a second source electrode, and a second drain electrode, a first gate insulating layer disposed between the first gate electrode and the first semiconductor pattern in a partial area of the first area, and a second gate insulating layer disposed between the first gate insulating layer and the first gate electrode, wherein the first gate insulating layer overlaps with the first semiconductor pattern, and the second gate insulating layer is disposed between the second gate electrode and the second semiconductor pattern.

Embodiments of the present disclosure may provide a method of manufacturing a display device including forming a first semiconductor pattern in a first area on a substrate and forming a first gate insulating layer on at least a portion of the first semiconductor pattern, forming a second semiconductor pattern in a second area on the substrate, and forming a second gate insulating layer on the first gate insulating layer and the second semiconductor pattern.

According to embodiments of the present disclosure, it is possible to provide a display device and a method of manufacturing the same capable of preventing interface contamination which may occur when disposing the driving circuits for driving a display panel.

According to embodiments of the present disclosure, it is possible to provide a display device and a method of manufacturing the same capable of preventing luminance defects of the display device when disposing the driving circuits for driving the display panel.

According to embodiments of the present disclosure, it is possible to provide a display device and a method of manufacturing the same capable of securing a process freedom of other components in the display panel when disposing the driving circuits for driving the display panel.

According to embodiments of the present disclosure, it is possible to provide a display device and a method of manufacturing the same capable of enabling process optimization by preventing a surface contamination when disposing a driving circuit for driving a display panel, and eliminating the need for additional processes for removing the surface contamination.

### BRIEF DESCRIPTION OF THE SEVERAL VIEWS OF THE DRAWINGS

FIG. 1 illustrates a configuration of a display device according to embodiments of the present disclosure.

FIG. 2 illustrates a subpixel and a peripheral circuit of a display device according to embodiments of the present disclosure.

FIG. 3 is a circuit diagram of a subpixel of a display device according to embodiments of the present disclosure.

FIG. 4 illustrates an example of a cross-sectional structure of a display device according to embodiments of the present disclosure.

FIG. 5 is an enlarged view of part A of FIG. 4.

FIG. 6 illustrates another example of a cross-sectional structure of a display device according to embodiments of the present disclosure.

FIGS. 7A and 7B are enlarged views of part B of FIG. 6.

FIGS. 8 and 9 illustrate another examples of a structure shown in FIG. 7A.

FIGS. 10A and 10B illustrate examples of a method of manufacturing a display device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The text “at least one of A or B” as used herein should be understood to mean “only A, only B, or both A and B.”

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, embodiments of the present disclosure will be described in detail with reference to the accompanying drawings.

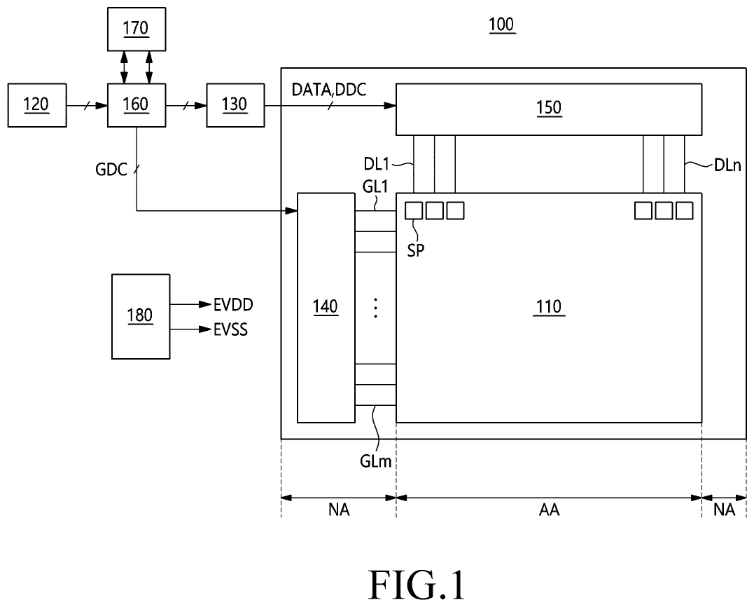

FIG. 1 illustrates a configuration of a display device according to embodiments of the present disclosure.

Referring to FIG. 1, a display device 100 may include an image processor 120, a deterioration compensation unit 160, a memory 170, a timing controller 130, a data driver 150, and a power supply unit 180. In addition, the display device 100 may include a display panel 110 on which the data driver 150 and a gate driver 140 are formed.

The image processor 120 may outputs a driving signal for driving various devices in addition to image data supplied from the outside. For example, the driving signal output from the image processor 120 may include a data enable signal, a vertical synchronization signal, a horizontal synchronization signal, and a clock signal.

The deterioration compensation unit 160 may calculate a deterioration compensation gain value of a subpixel SP of the display panel based on a sensing voltage Vsen supplied from the data driver 150, may calculate a dimming weight value based on the calculated degradation compensation gain value, may modulate the input image data Idata of each subpixel SP in the current frame based on the calculated degradation compensation gain value and dimming weight value, and then may supply the modulated image data Mdata to the timing controller 130.

The timing controller 130 may receive image data modulated from the deterioration compensation unit 160 as well as a driving signal. The timing controller 130 may generate and output a gate timing control signal GDC for controlling the operation timing of the gate driver 140 and a data timing control signal DDC and a data timing control signal DDC for controlling the operation timing of the data driver 150 based on the driving signal input from the image processor 120.

In addition, the timing controller 130 may control the operation timing of the gate driver 140 and the data driver 150 to obtain at least one sensing voltage Vsen from each subpixel SP to supply to the degradation compensation unit 160.

The gate driver 140 may output a scan signal to the display panel 110 in response to the gate timing control signal GDC supplied from the timing controller 130. The gate driver 140 may outputs the scan signal through a plurality of gate lines GL1 to GLm. The gate driver 140 may be formed in the form of an integrated circuit (IC), but is not limited thereto. In particular, the gate driver 140 may be formed in a gate-in-panel (GIP) structure formed by stacking thin film transistors directly on a substrate inside the display device 100. The GIP structure may include a plurality of circuits such as shift registers and level shifters.

The data driver 150 may output a data voltage to the display panel 110 in response to the data timing control signal DDC input from the timing control unit 130. The data driver 150 may sample and latch a digital data signal DATA supplied from the timing controller 130, and convert into an analog data voltage based on a gamma voltage.

The data driver 150 may output a data voltage through a plurality of data lines DL1 to DLn.

In addition, the data driver 140 may supply the sensing voltage Vsen input from the display panel 110 through a sensing voltage read-out line to the deterioration compensation unit 160.

In this case, the data driver 150 may be mounted on the display panel 110 in the form of an integrated circuit (IC) or may be formed directly on the display panel 110, but is not limited thereto.

The power supply unit 180 may output and supply a high potential driving voltage EVDD and a low potential driving voltage EVSS to the display panel 110. The high potential driving voltage VDD and the low potential driving voltage EVSS may be supplied to the display panel 110 through the power line. In this case, the voltage output from the power supply unit 180 may be output to the data driver 150 or the gate driver 140, and may be used to drive the data driver 150 or the gate driver 140.

The display panel 110 may display the image in response to a data voltage and a scan signal supplied from the data driver 150 and the gate driver 140, which may be disposed in the non-display area NA, and power supplied from the power supply unit 180.

The display area AA of the display panel 110 may include of a plurality of subpixels SP, and display an actual image. The subpixel SP may include a red subpixel, a green subpixel, and a blue subpixel, or may include a white (W) subpixel, a red (R) subpixel, a green (G) subpixel, and a blue (B) subpixel. In this case, the W, R, G, and B subpixels SP may all be formed with the same area, but may also be formed with different areas.

The memory 170 may store a look-up table for degradation compensation gains, and may also store the degradation compensation timing information of the organic light emitting device of the subpixel SP. In this case, the degradation compensation timing of the organic light emitting device may be based on the number of times or driving time of the organic light emitting display panel.

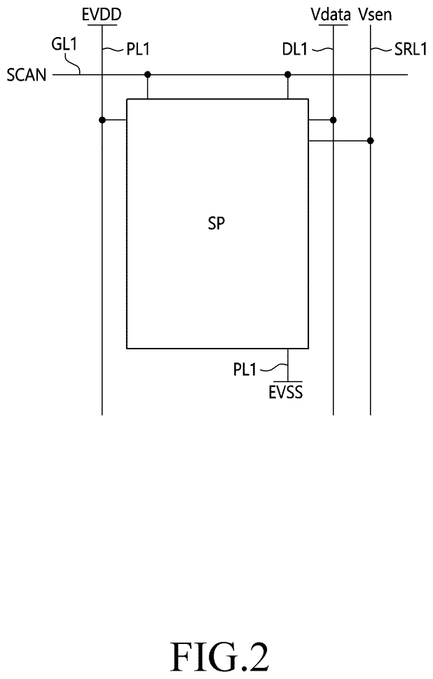

FIG. 2 illustrates a subpixel and a peripheral circuit of a display device according to embodiments of the present disclosure.

Referring to FIG. 2, one subpixel SP may be connected to a gate line GL1, a data line DL1, a sensing voltage read-out line SRL1, and a power line PL1. A method of the subpixel SP and the number of transistors and capacitors may be determined depending on a circuit configuration.

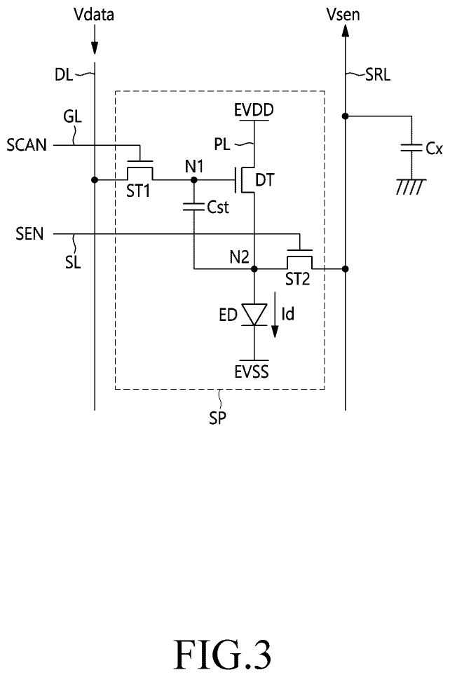

FIG. 3 is a circuit diagram of a subpixel of a display device according to embodiments of the present disclosure.

Referring to FIG. 3, the display device 100 may include a gate line GL, a data line DL, a power line PL, and a sensing line SL which intersect with each other to define a subpixel SP. Each subpixel SP may include a driving thin film transistor DT, a light emitting device ED, a storage capacitor Cst, a first switch thin film transistor ST1, and a second switch thin film transistor ST2.

The light emitting device ED may include an anode electrode connected to a second node N2, a cathode electrode connected to an input terminal of a low potential driving voltage EVSS, and an organic emission layer located between the anode electrode and the cathode electrode.

The driving thin film transistor DT may control the current Id flowing through the light emitting device ED according to a gate-source voltage Vgs. The driving thin film transistor DT may include a gate electrode connected to a first node N1, a drain electrode connected to the power line PL to provide a high potential driving voltage EVDD, and a source electrode connected to the second node N2.

The storage capacitor Cst may be connected between the first node N1 and the second node N2.

When the display panel 110 is driven, the first switch thin film transistor ST1 may apply the data voltage Vdata charged in the data line DL to the first node N1 in response to a gate signal SCAN to turn on the driving thin film transistor DT. The first switch thin film transistor ST1 may include a gate electrode connected to the gate line GL to input the scan signal SCAN, a drain electrode connected to the data line DL to input the data voltage Vdata, and a source electrode connected to the first node N1.

The second switch thin film transistor ST2 may switch the current between the second node N2 and the sensing voltage read-out line SRL in response to the sensing signal SEN, thereby charging a source voltage of the second node N2 in a sensing capacitor Cx of the sensing voltage read-out line SRL. The second switch thin film transistor ST2 may switch the current between the second node N2 and the sensing voltage read-out line SRL in response to the sensing signal SEN when driving the display panel 110, thereby resetting a source voltage of the driving thin film transistor DT to an initialization voltage Vpre. In this case, a gate electrode of the second switch thin film transistor ST2 may be connected to the sensing line SL, a drain electrode may be connected to the second node N2, and the source electrode may be connected to the sensing voltage read-out line SRL.

Meanwhile, in FIG. 3, it has been described an organic light emitting display device with a 3T1C structure including three thin film transistors and one storage capacitor as an example, but the organic light emitting display device according to the present disclosure is not limited thereto, and may be applied to various structures such as 4T1C, 5T1C, 6T1C, 7T1C, and 8T1C.

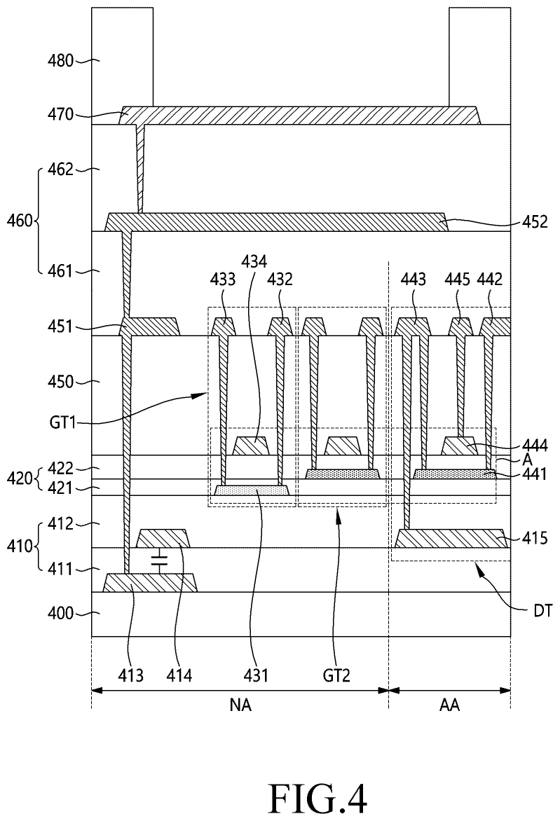

FIG. 4 illustrates an example of a cross-sectional structure of a display device according to embodiments of the present disclosure.

Referring to FIG. 4, there may be disposed a driving thin film transistor DT, a first thin film transistor GT1, and a second thin film transistor GT2 on a substrate 400.

The substrate 400 may be divided into a display area AA where the subpixel SP is disposed, and a non-display area NA outside the display area AA. The driving thin film transistor DT may be located in the display area AA on the substrate 400, and the first thin film transistor GT1 and the second thin film transistor GT2 may be located in the non-display area NA on the substrate 400.

The first thin film transistor GT1 and the second thin film transistor GT2 may be any one of a plurality of thin film transistors constituting a gate driver, and in particular, may be disposed in a GIP area, which is an area where the gate driver is disposed, in the non-display area NA.

Hereinafter, it will be described a cross-sectional structure of the display device including the first thin film transistor GT1, the second thin film transistor GT2, and the driving thin film transistor DT.

A plurality of buffer layers 410 may be disposed on the substrate 400. The buffer layer 410 may be a single layer or a multi-layer. If the buffer layer 410 is a multi-layer, the buffer layers 410 may include a first buffer layer 411 and a second buffer layer 412 disposed on the first buffer layer 411.

The buffer layer 410 may function to block various types of defects leaking from the substrate 400, and may be made of silicon nitride or silicon oxide.

A capacitor may be disposed in the area where the buffer layer 410 is disposed. The capacitor may include a first capacitor electrode 413 and a second capacitor electrode 414.

The first buffer layer 411 may be disposed between the first capacitor electrode 413 and the second capacitor electrode 414. The first capacitor electrode 413 and the second capacitor electrode 414 may be formed as a single layer or multi-layers of molybdenum (Mo), copper (Cu), titanium (Ti), aluminum (Al), chromium (Cr), gold (Au), nickel (Ni), neodymium (Nd), tungsten (W), or an alloy thereof, but is not limited thereto.

A blocking layer 415 may be disposed on the first buffer layer 411. The blocking layer 415 may be disposed between the first buffer layer 411 and the second buffer layer 412, and may be disposed under a second semiconductor pattern 441.

The blocking layer 415 may be formed as a single layer or multi-layers of one of molybdenum (Mo), copper (Cu), titanium (Ti), aluminum (Al), chromium (Cr), gold (Au), nickel (Ni), neodymium (Nd), tungsten (W), or an alloy thereof. The blocking layer 415 may prevent the semiconductor pattern from malfunctioning when light incident from outside the display device irradiates the semiconductor pattern.

The above-described first capacitor electrode 413 may perform the same role as the blocking layer 415.

A plurality of gate insulating layers 420 and a first semiconductor pattern 431 of the first thin film transistor GT1 may be disposed on the buffer layer 410.

The plurality of gate insulating layers 420 may include a first gate insulating layer 421 and a second gate insulating layer 422 disposed on the first gate insulating layer 421.

The first gate insulating layer 421 may serve to insulate between the first semiconductor pattern 431 and a first gate electrode 434, and may also serve to insulate between the first semiconductor pattern 431 and the second semiconductor pattern 441.

The first gate insulating layer 421 or the second gate insulating layer 422 may be formed of an insulating inorganic material such as silicon nitride or silicon oxide. Additionally, the first gate insulating layer 421 may contain some fluorine F.

The first semiconductor pattern 431 may be made of oxide, and may have high mobility. For example, the first semiconductor pattern 431 may be a double layer or triple layer containing indium zinc oxide (IZO). If the first semiconductor pattern 431 is a double layer, it may be (F)IZO/IGZO, and if it is a triple layer, it may be IGZO/(F)IZO/IGZO.

However, embodiments of the present disclosure are not necessarily limited thereto, and the first semiconductor pattern 431 may be made of amorphous silicon (a-Si) or a polycrystalline semiconductor. However, there is exemplified a case where the first semiconductor pattern 431 is made of oxide.

The first semiconductor pattern 431 may include a first channel area where a channel is formed when the first thin film transistor GT1 is driven. The first semiconductor pattern 431 may include a first source area and a first drain area, which become to be conductive through a doping process on both sides of the first channel area. The first source area may refer to a portion of the first semiconductor pattern 431 connected to a first source electrode 432, and the first drain area may refer to a portion of the first semiconductor pattern 431 connected to a first drain electrode 433.

A semiconductor pattern of the second thin film transistor GT2 and the second semiconductor pattern 441 of the driving thin film transistor DT may be disposed on the first gate insulating layer 421.

The second semiconductor pattern 441 may be made of oxide and may have low mobility. As an example, the second semiconductor pattern 441 may include indium gallium zinc oxide (IGZO).

However, it is not necessarily limited thereto, and the second semiconductor pattern 441 may be made of amorphous silicon (a-Si) or a polycrystalline semiconductor. However, there is exemplified a case where the second semiconductor pattern 441 is made of oxide.

The second semiconductor pattern 441 may include a second channel area where a channel is formed when the driving thin film transistor DT is driven. The second semiconductor pattern 441 may include a second source area and a second drain area, which become to be conductive through a doping process on both sides of the second channel area. The second source area may refer to a portion of the second semiconductor pattern 441 connected to a second source electrode 442, and the second drain area may refer to a portion of the second semiconductor pattern 441 connected to a second drain electrode 443.

A second gate insulating layer 422 may be disposed on the second semiconductor pattern 441.

On the second gate insulating layer 422, there may be disposed an interlayer insulating layer 450, a first gate electrode 434 of the first thin film transistor GT1, a gate electrode of the second thin film transistor GT2, and a second gate electrode 444 of the driving thin film transistor DT.

The interlayer insulating layer 450 may be formed of an insulating material such as silicon nitride or silicon oxide.

The first gate electrode 434 of the first thin film transistor GT1, the gate electrode of the second thin film transistor GT2, and the second gate electrode 444 of the driving thin film transistor DT may be disposed on the same layer.

The first gate electrode 434 of the first thin film transistor GT1, the gate electrode of the second thin film transistor GT2, and the second gate electrode 444 of the driving thin film transistor DT may be formed as a single layer or multiple layers made of one of molybdenum (Mo), copper (Cu), titanium (Ti), aluminum (Al), chromium (Cr), gold (Au), nickel (Ni), neodymium (Nd), tungsten (W), or an alloy thereof, but is not limited thereto.

On the interlayer insulating layer 450, there may be disposed an planarization layer 460, a first source electrode 432 and a first drain electrode 433 of the first thin film transistor GT1, and a second source electrode 442, a second drain electrode 443, and a gate line electrode 445 of the driving thin film transistor DT.

In addition, the source and drain electrodes and a first connection electrode 451 of the second thin film transistor GT2 may be disposed on the interlayer insulating layer 450.

The first source electrode 432 and the first drain electrode 433 of the first thin film transistor GT1 may be electrically connected to the first semiconductor pattern 431 through a hole penetrating the interlayer insulating layer 450, the second gate insulating layer 422, and the first gate insulating layer 421.

The second source electrode 442 and the second drain electrode 443 of the driving thin film transistor DT may be electrically connected to the second semiconductor pattern 441 through a hole penetrating the interlayer insulating layer 450 and the second gate insulating layer 422, and may be electrically connected to the blocking layer 415 through a hole penetrating the interlayer insulating layer 450, the second gate insulating layer 422, the first gate insulating layer 421, and the second buffer layer 412.

In addition, the second source electrode 442 may be electrically connected to the second semiconductor pattern 441 through a hole penetrating the interlayer insulating layer 450 and the second gate insulating layer 422.

The gate line electrode 445 may be electrically connected to the second gate electrode 444, and may serve as a wiring for supplying a gate voltage to the second gate electrode 444.

The first connection electrode 451 may be electrically connected to the first capacitor electrode 413 through a hole penetrating the interlayer insulating layer 450, the second gate insulating layer 422, the first gate insulating layer 421, the second buffer layer 412, and the first buffer layer 411. The first connection electrode 451 may electrically connect a second connection electrode 452 and a first capacitor electrode 413.

The planarization layer 460 may include a first planarization layer 461 and a second planarization layer 462 disposed on the first planarization layer 461.

The planarization layer 460 may protect various thin film transistors disposed below, and may alleviate or flatten steps caused by various patterns.

The planarization layer 460 may be formed of at least one organic insulating material such as BCB (BenzoCycloButene), acryl resin, epoxy resin, phenolic resin, polyamide resin, or polyimide resin, but is not limited thereto.

The second connection electrode 452 may be disposed between the first planarization layer 461 and the second planarization layer 462.

The second connection electrode 452 may electrically connect the first connection electrode 451 and an anode electrode 470.

The first capacitor electrode 413 may be electrically connected to the anode electrode 470 through the first connection electrode 451 and the second connection electrode 452.

The first source electrode 432, the first drain electrode 433, the second source electrode 442, the second drain electrode 443, the first connection electrode 451, and the second connection electrode 452 may be made of the same material. For example, each electrode may be made of a triple layer of titanium (Ti), aluminum (Al), and titanium (Ti). However, it is not limited thereto.

An anode electrode 470 may be disposed on the second planarization layer 462.

In FIG. 4, it is illustrated a case in which the anode electrode 470 is only connected to the first capacitor electrode 413 in the non-display area NA, but the anode electrode 470 may be electrically connected to the source electrode 442 of the driving thin film transistor DT within the display area AA.

A bank layer 480 may be disposed on the anode electrode 470 and the second planarization layer 462. The bank layer 480 may further include a spacer.

The bank layer 480 may have an opening area on the anode electrode 470.

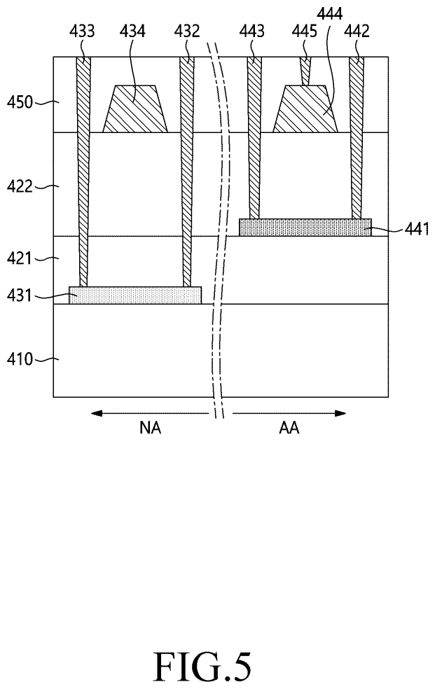

FIG. 5 is an enlarged view of part A of FIG. 4.

Referring to FIG. 5, as described above, the display device may include a plurality of gate insulating layers 420.

In particular, among the plurality of gate insulating layers 420, the first gate insulating layer 421 may be disposed on the first semiconductor pattern 431, and may be disposed in the entire area including the display area AA and the non-display area NA. In addition, the first gate insulating layer 421 may be located between the first semiconductor pattern 431 and the second semiconductor pattern 441.

In this case, as shown in FIG. 5, in order for the first gate insulating layer 421 to be disposed on the first semiconductor pattern 431, there is required to first form the first semiconductor pattern 431 on the buffer layer 410, and then deposit the first gate insulating layer 421. That is, the process of forming the first semiconductor pattern 431 is required to be preceded.

The process of forming the first semiconductor pattern 431 may include depositing an oxide layer (e.g., (F)IZO/IGZO or IGZO/(F)IZO/IGZO) on the entire buffer layer 410, and then applying photoresist (PR) on the oxide layer, and patterning the oxide layer through exposure and etching.

However, in the process of patterning the oxide layer, photoresist residues may remain on un upper portion of the oxide layer, which may cause the contamination of the upper interface of the oxide layer. In addition, since oxygen is removed from the upper interface of the oxide layer, it is required a process for oxygen compensation. However, the characteristics of the transistor may deteriorate due to the oxygen compensation process.

In addition, in the case that the first gate insulating layer 421 is located between the first semiconductor pattern 431 and the second semiconductor pattern 441, a lot of traps may occur at the interface of the second semiconductor pattern 441 due to the large amount of oxygen contained in the first gate insulating layer 421. As a result, the second semiconductor pattern 441 may be deteriorated, which may cause a problem in which the current characteristics of the driving thin film transistor DT may deteriorate.

In addition, as the second gate insulating layer 422 is disposed on the first gate insulating layer 421 in all areas on the substrate, when forming the second gate insulating layer 422, the formation conditions may be limited so as not to affect the insulating characteristics of the first gate insulating layer 421.

Hereinafter, it will be described a solution to the above-described problems with reference to the drawings.

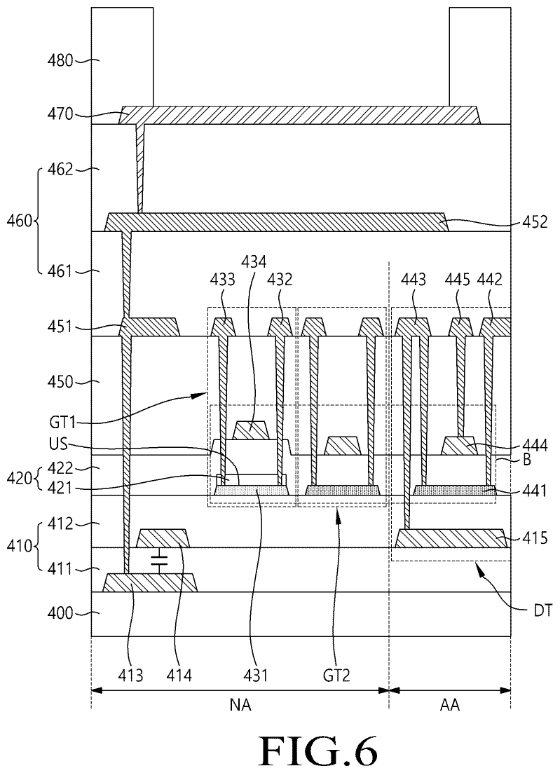

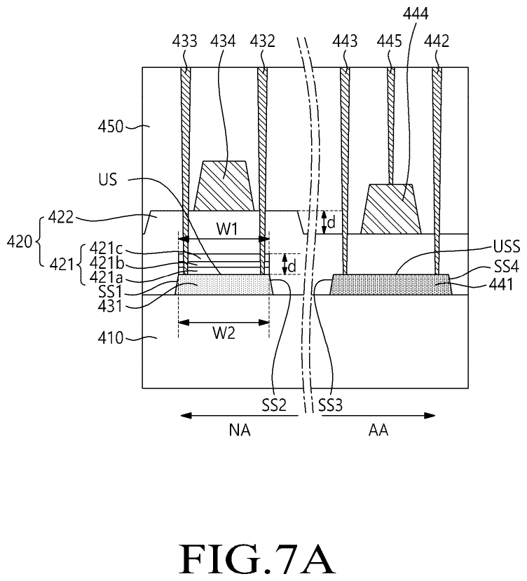

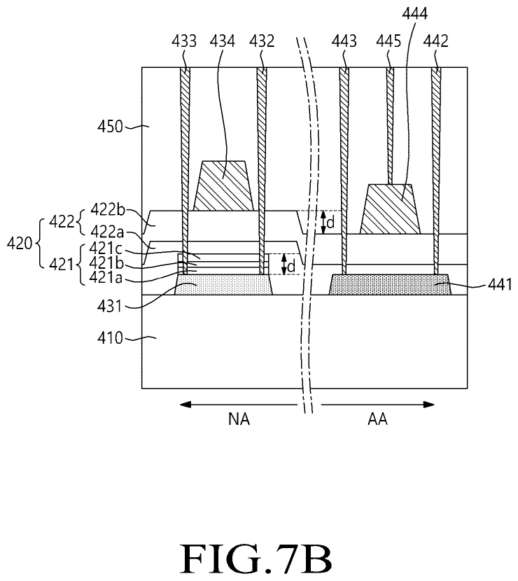

FIG. 6 illustrates another example of a cross-sectional structure of a display device according to embodiments of the present disclosure. FIGS. 7A and 7B are enlarged views of part B of FIG. 6.

The cross-sectional structure of the display device shown in FIGS. 6, 7A, and 7B are the same as the cross-sectional structure of the display device described with reference to FIGS. 4 and 5, except that the first gate insulating layer 421 is disposed only in a partial area on the first semiconductor pattern 431, and accordingly, the first semiconductor pattern 431 and the second semiconductor pattern 441 are disposed on the same layer, so that it will be omitting overlapping descriptions.

Referring to FIGS. 6 and 7A, the first gate insulating layer 421 may be disposed in a portion of the non-display area NA.

Specifically, as shown in FIG. 6, the first gate insulating layer 421 may be disposed on an upper surface US of the first semiconductor pattern 431 of the first thin film transistor GT1 included in the GIP area of the non-display area NA.

In an embodiment, the first gate insulating layer 421 may be formed as a triple layer including a first layer 421a, a second layer 421b disposed on the first layer 421a, and a third layer 421c disposed on the second layer 421b.

The first layer 421a and the third layer 421c of the first gate insulating layer 421 may include SiOx, and the second layer 421b may include SiNx:F or SiOx:F.

A width W1 of each layer 421a, 421b and 421c of the first gate insulating layer 421 may be equal to or greater than a width W2 of the upper surface US of the first semiconductor pattern 431. For example, FIG. 7A illustrates that the width W1 of the first gate insulating layer 421 is equal to the width W2 of the upper surface US of the first semiconductor pattern 431. On the other hand, FIGS. 7B, 8, and 9 illustrate that the width W1 of the first gate insulating layer 421 is greater than the width W2 of the upper surface US of the first semiconductor pattern 431.

As the second layer 421b of the first gate insulating layer 421 includes SiN:F or SiO:F which does not contain hydrogen, there may partially prevent that the first semiconductor pattern 431 is made into a conductor by hydrogen.

In FIG. 7A, it is illustrated a case where the first gate insulating layer 421 is a triple layer, but embodiments of the present disclosure are not necessarily limited thereto, and the first gate insulating layer 421 may be a single layer or a double layer.

If the first gate insulating layer 421 is a single layer, the first gate insulating layer 421 may include SiOx, SiN:F, or SiO:F.

If the first gate insulating layer 421 is a double layer, at least one of the double layers may include SiN:F or SiO:F. The first gate insulating layer 421 shown in FIGS. 6, 7A, and 7B may be formed by being deposited in the entire surface on the first semiconductor pattern 431 and then applying photoresist, exposing, and etching. In this case, the process of forming the first gate insulating layer 421 and the process of forming the first semiconductor pattern 431 may be performed together.

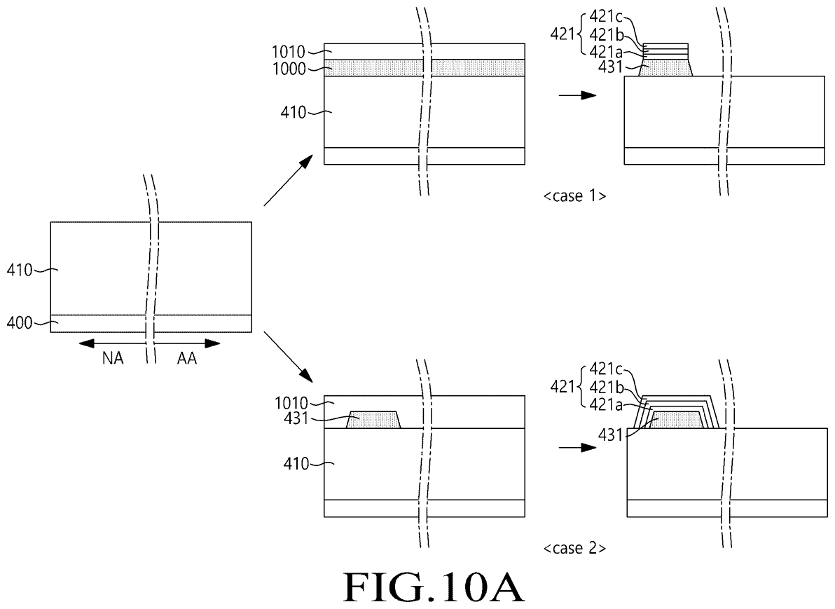

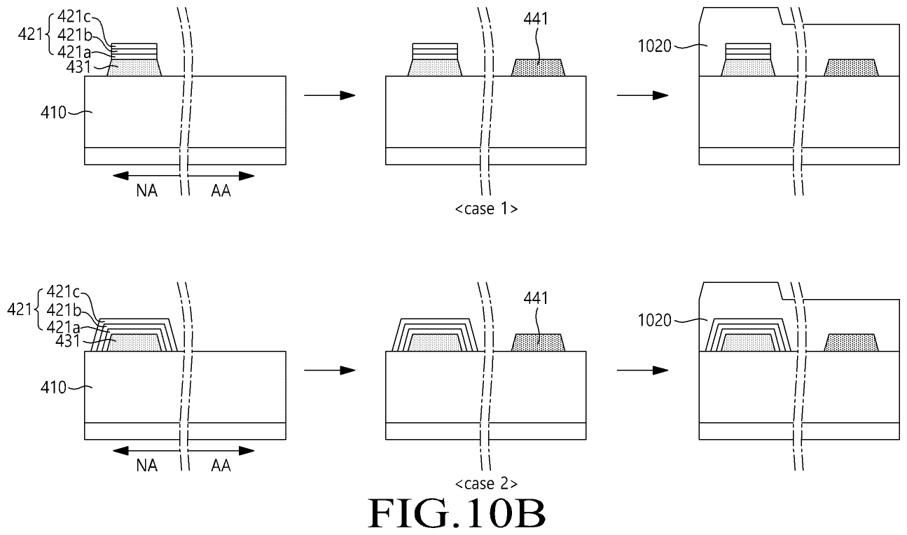

It will be described later a detailed description of the process of forming the first gate insulating layer 421 on the upper surface US of the first semiconductor pattern 431 and the process of forming the first semiconductor pattern 431 with reference to FIGS. 10A and 10B.

In the case that the first gate insulating layer 421 is formed to be disposed on the upper surface US of the first semiconductor pattern 431, the first gate insulating layer 421 may not be disposed in the display area AA. That is, the first gate insulating layer 421 may not be disposed on the second semiconductor pattern 441 of the driving thin film transistor DT.

Although FIG. 6 illustrates a structure in which the first gate insulating layer 421 is formed only on the first semiconductor pattern 431 of the first thin film transistor GT1, but an embodiment is not necessarily limited thereto, and the first gate insulating layer 421 may be disposed only on the semiconductor pattern of the second thin film transistor GT2. However, for convenience of explanation, hereinafter, it will be described a structure in which the first gate insulating layer 421 is formed only on the first semiconductor pattern 431 of the first thin film transistor GT1 as an example.

Since the first gate insulating layer 421 is disposed only in the area on the first semiconductor pattern 431 of the first thin film transistor GT1 disposed in the GIP area, a semiconductor pattern of the second thin film transistor GT2 and a second semiconductor pattern 441 of the driving thin film transistor DT may be disposed on the buffer layer 410.

That is, the first semiconductor pattern 431 of the first thin film transistor GT1, the semiconductor pattern of the second thin film transistor GT2, and the second semiconductor pattern 441 of the driving thin film transistor DT may be disposed on the same layer.

The second gate insulating layer 422 may be disposed on the first gate insulating layer 421, the semiconductor pattern of the second thin film transistor GT2, and the second semiconductor pattern 441 of the driving thin film transistor DT.

Referring to FIGS. 6 and 7A, the second gate insulating layer 422 may be formed as a single layer.

In the case that the second gate insulating layer 422 is a single layer, the second gate insulating layer 422 may include SiOx, SiNx:F, or SiOx:F. If the second gate insulating layer 422 includes SiN:F or SiO:F, which does not contain hydrogen, it is possible to partially prevent the first semiconductor pattern 431 from becoming a conductor due to hydrogen.

Referring to FIG. 7B, the second gate insulating layer 422 may be formed as a double layer including a first layer 422a and a second layer 422b disposed on the first layer 422a.

The first layer 422a of the second gate insulating layer 422 may include SiNx:F or SiOx:F, and the second layer 422b may include SiOx. Alternatively, the first layer 422a of the second gate insulating layer 422 may include SiOx, and the second layer 422b may include SiNx:F or SiOx:F.

The first layer 422a of the second gate insulating layer 422 may block oxygen flowing out of the second layer 422b from flowing into the second semiconductor pattern 441. As shown in FIGS. 6, 7A and 7B, in the case that the first gate insulating layer 421 is disposed only on the upper surface US of the first semiconductor pattern 431, a side surface (e.g., a first side surface SS1 or a second side surface SS2) of the first semiconductor pattern 431 may contact the second gate insulating layer 422. In some embodiments, both first side surface SS1 and the second side surface SS2 of the first semiconductor pattern 431 may contact the second gate insulating layer 422.

The second gate insulating layer 422 may be formed along a step of the layer disposed below, so that the second gate insulating layer 422 may be formed to be higher in an area where the first gate insulating layer 421 is disposed than in an area where the first gate insulating layer 421 is not disposed.

As shown in FIGS. 7A and 7B, if a thickness of the first gate insulating layer 421 is ‘d’, a vertical height of the upper surface of the second gate insulating layer 422 disposed on the area where the first gate insulating layer 421 is disposed may be greater than a vertical height of the upper surface of the second gate insulating layer 422 disposed on the area where the first gate insulating layer 421 is not disposed by a value of ‘d’.

The first gate electrode 434 of the first thin film transistor GT1, the gate electrode of the second thin film transistor GT2, and the second gate electrode 444 of the driving thin film transistor DT may be disposed on the second gate insulating layer 422.

The first gate electrode 434 of the first thin film transistor GT1, the gate electrode of the second thin film transistor GT2, and the second gate electrode 444 of the driving thin film transistor DT may be formed on the same layer. However, since the upper surface of the second gate insulating layer 422 is formed higher in the area where the first gate insulating layer 421 is disposed, a height of the upper surface of the first gate electrode 434 of the first thin film transistor GT1 may be greater than a height of the upper surface of the gate electrode of the second thin film transistor GT2 and the second gate electrode 444 of the driving thin film transistor DT by the thickness of the first gate insulating layer 421.

That is, a distance from the first semiconductor pattern 431 to the first gate electrode 434 may be greater than a distance from the second semiconductor pattern 441 to the second gate electrode 444 by the thickness of the first gate insulating layer 421.

An interlayer insulating layer 450 may be disposed on the second gate insulating layer 422, the first gate electrode 434, and the second gate electrode 444.

A thickness of the interlayer insulating layer 450 may be smaller in the area where the first gate insulating layer 421 is disposed by the thickness of the first gate insulating layer 421 than in the area where the first gate insulating layer 421 is not disposed.

That is, the height of the upper surface of the interlayer insulating layer 450 may be the same in the area where the first gate insulating layer 421 is disposed and in the area where the first gate insulating layer 421 is not disposed.

Hereinafter, it will be described another example of a structure in which the first gate insulating layer 421 is disposed.

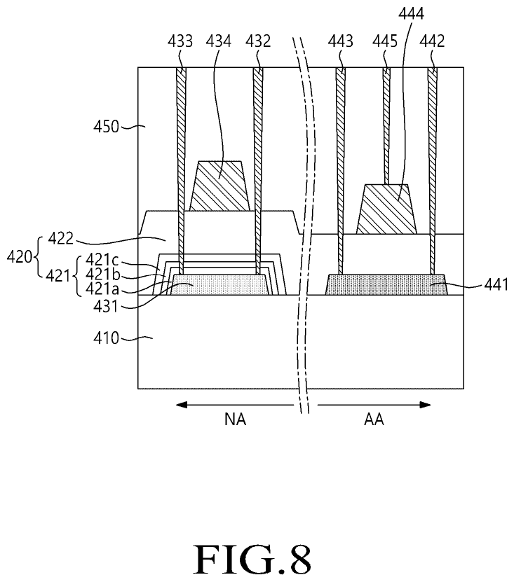

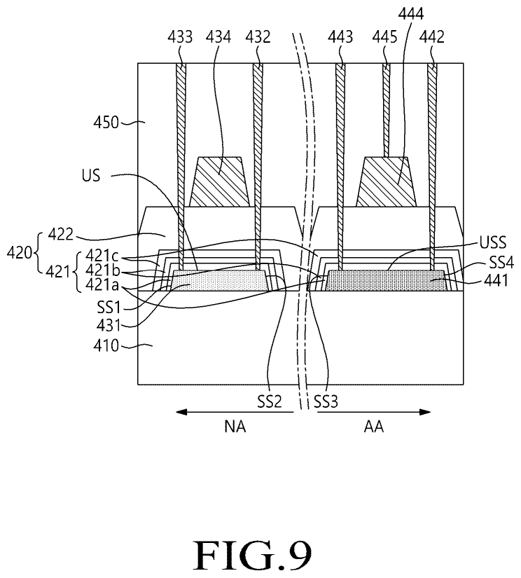

FIGS. 8 and 9 illustrate another examples of a structure shown in FIG. 7A.

The cross-sectional structure shown in FIG. 8 is the same as the cross-sectional structure described with reference to FIGS. 7A and 7B except that the first gate insulating layer 421 covers not only the upper surface US but also the side surfaces SS1, SS2 of the first semiconductor pattern 431. Therefore, it will be omitting redundant explanations. That is, the first gate insulating layer 421 shown in FIG. 8 is shown as a triple layer, but is not limited thereto, and may be a single layer or a double layer.

Referring to FIG. 8, the first gate insulating layer 421 may be disposed to cover both the upper and side surfaces US, SS1, SS2 of the first semiconductor pattern 431 of the first thin film transistor GT1.

The second gate insulating layer 422 may be disposed on the first gate insulating layer 421 and the second semiconductor pattern 441.

In FIG. 8, the second gate insulating layer 422 is shown as a single layer, but is not limited thereto, and may be a double layer. For example, the second gate insulating layer 422 may include a first layer and a second layer on the first layer, as described above with reference to FIG. 7B.

Here, the first layer may include SiNx:F or SiOx:F, and the second layer 422b may include SiOx. Alternatively, the first layer 422a of the second gate insulating layer 422 may include SiOx, and the second layer 422b may include SiNx:F or SiOx:F.

As the first gate insulating layer 421 is disposed to cover both the upper and side surfaces of the first semiconductor pattern 431, the first semiconductor pattern 431 may not contact the second gate insulating layer 422.

The first gate insulating layer 421 may be formed by being deposited in the entire surface on the first semiconductor pattern 431, and then applying photoresist, exposing and etching. In this case, a process of forming the first gate insulating layer 421 may be performed after a process of forming the first semiconductor pattern 431.

It will be described later a detailed description of the process of forming the first semiconductor pattern 431 and the process of forming the first gate insulating layer 421 to cover both the upper and side surfaces of the first semiconductor pattern 431 with reference to FIGS. 10A and 10B.

Since the cross-sectional structure shown in FIG. 9 is the same as the cross-sectional structure described with reference to FIG. 8 except that the first gate insulating layer 421 is disposed not only on the first semiconductor pattern 431 but also on the second semiconductor pattern 441 of the driving thin film transistor DT, it will be omitting overlapping description. That is, the first gate insulating layer 421 shown in FIG. 8 is exemplified as a triple layer, but is not limited thereto, and may be a single layer or a double layer. Referring to FIG. 9, the first gate insulating layer 421 may be disposed to cover both the upper surface USS and side surfaces (e.g., a third side surface SS3, a fourth side surface SS4) of the second semiconductor pattern 441 of the driving thin film transistor DT disposed in the display area AA.

The second gate insulating layer 422 may be disposed on the first gate insulating layer 421 on the first semiconductor pattern 431 and the first gate insulating layer 421 on the second semiconductor pattern 441.

In FIG. 9, the second gate insulating layer 422 is shown as a single layer, but is not limited thereto, and may be a double layer. The second gate insulating layer 422 may include a first layer and a second layer on the first layer, as described above with reference to FIG. 7B.

Here, the first layer may include SiNx:F or SiOx:F, and the second layer 422b may include SiOx. Alternatively, the first layer 422a of the second gate insulating layer 422 may include SiOx, and the second layer 422b may include SiNx:F or SiOx:F.

As the first gate insulating layer 421 is disposed to cover both the upper surface USS and side surfaces SS3, SS4 of the second semiconductor pattern 441, the second semiconductor pattern 441 may not contact the second gate insulating layer 422.

FIG. 9 illustrates a structure in which the first gate insulating layer 421 covers both the upper surface US and side surfaces SS1, SS2 of the first semiconductor pattern 431 and the upper surface USS and side surfaces SS3, SS4 of the second semiconductor pattern 441, but is not necessarily limited thereto. The first gate insulating layer 421 may cover only the upper surface US of the first semiconductor pattern 431 and the upper surface of the second semiconductor pattern 441.

In this case, the second gate insulating layer 422 may contact the side surface of the first semiconductor pattern 431 and the side surface of the second semiconductor pattern 441. The second gate insulating layer 422 is shown as a single layer, but may also be a double layer, and at least one layer may include SiNx:F or SiOx:F.

The first gate insulating layer 421 formed on the second semiconductor pattern 431 may be a layer formed in the same manner as the first gate insulating layer 421 formed on the first semiconductor pattern 431. In this case, the process of forming the first gate insulating layer 421 may be performed after the process of forming the second semiconductor pattern 441.

The first gate insulating layer 421 disposed on the second semiconductor pattern 441 may have the same thickness as the first gate insulating layer 421 disposed on the first semiconductor pattern 441, however, is not limited thereto.

if the first gate insulating layer 421 disposed on the second semiconductor pattern 441 has the same thickness as the first gate insulating layer 421 disposed on the first semiconductor pattern 441, the height of the upper surface of the second gate insulating layer 422 may be the same in an area where the first semiconductor pattern 431 is disposed and an area where the second semiconductor pattern 441 is disposed.

Accordingly, the height of the upper surface of the first gate electrode 434 of the first thin film transistor GT1 and the upper surface of the second gate electrode 444 of the driving thin film transistor DT may be the same.

Hereinafter, it will be described a method of manufacturing a display device described with reference to FIGS. 6 to 9.

FIGS. 10A and 10B illustrate examples of a method of manufacturing a display device according to embodiments of the present disclosure.

Referring to FIG. 10A, a buffer layer 410 may be formed on a substrate.

Referring to <case 1> of FIG. 10A, a first oxide layer 1000 may be formed on the buffer layer 410.

The first oxide layer 1000 may be made of the same material as the first semiconductor pattern 431. That is, as described above, the first oxide layer 1000 may be a double layer or triple layer containing IZO. If the first semiconductor pattern 431 is a double layer, it may be (F)IZO/IGZO, and if it is a triple layer, it may be IGZO/(F)IZO/IGZO. However, it is not limited thereto.

The first oxide layer 1000 may be deposited on the buffer layer 410 in both the display area AA and the non-display area NA.

A first insulating material layer 1010 may be formed on the first oxide layer 1000.

The first insulating material layer 1010 may be formed of an insulating inorganic material such as silicon nitride or silicon oxide. Additionally, the first insulating material layer 1010 may contain some fluorine (F).

A photoresist (not shown) may be applied on the first insulating material layer 1010.

After the photoresist (not shown) is applied, exposure may be performed using an etch mask (hereinafter referred to as a first etch mask) to form the first semiconductor pattern 431.

After exposure and development, an etching process may proceed.

The etching process may be a process of removing the exposed portion. However, it is not limited thereto, and depending on the type of photoresist, it may be a process of removing unexposed areas.

The first insulating material layer 1010 and the first oxide layer 1000 may be etched together. In detail, etching may be performed in the order that the first insulating material layer 1010 is removed first and then the first oxide layer 1000 is removed.

The first insulating material layer 1010 may be etched using a dry etching process, and the first oxide layer 1000 may be etched using a wet etching process. However, it is not necessarily limited thereto.

A first gate insulating layer 421 may be formed by removing a part of the first insulating material layer 1010 through an etching process. Here, the first gate insulating layer 421 may be a triple layer including a first layer 421a, a second layer 421b, and a third layer 421c, but is not limited thereto.

Referring to <case 1> of FIG. 10A, the first gate insulating layer 421 may be located on the upper surface of the first semiconductor pattern 431 in a partial area within the non-display area NA.

After forming the first gate insulating layer 421, the first oxide layer 1000 may be removed through an etching process to form a first semiconductor pattern 431.

The first semiconductor pattern 431 may have a greater width in the horizontal direction than the first gate insulating layer 421, but is not necessarily limited thereto.

As described above, the first gate insulating layer 421 and the first semiconductor pattern 431 may be formed using a first etch mask, that is, one mask.

In addition, since the first semiconductor pattern 431 is etched after the first gate insulating layer 421 is formed on the first semiconductor pattern 431, there may be omitted the process of directly applying the photoresist on the first oxide layer 1000, and patterning through exposure and etching.

That is, during the process of patterning the oxide layer, there may be no problem of residues such as photoresist remaining on the top of the oxide layer.

Referring to <case 2> of FIG. 10A, a first semiconductor pattern 431 may be formed on the buffer layer 410.

The first semiconductor pattern 431 may be formed before the first insulating material layer 1010 is formed. Specifically, the first semiconductor pattern 431 may be formed through the process of depositing a first oxide layer on the entire surface as in <case 1>, then applying a photoresist to the first oxide layer, and exposing and etching using a first etch mask.

The first semiconductor pattern 431 may be formed in the non-display area NA, particularly in the GIP area.

A first insulating material layer 1010 may be formed on the first semiconductor pattern 431 and the buffer layer 410.

The first insulating material layer 1010 may be disposed in the entire area including the display area AA and the non-display area NA.

A photoresist (not shown) may be applied on the first insulating material layer 1010.

After the photoresist (not shown) is applied, exposure may be performed using an etch mask (hereinafter referred to as a second etch mask) to form the first gate insulating layer 421.

After exposure and development, the etching process may proceed.

Here, the etching process may be a process of removing a portion of the first insulating material layer 1010.

The first gate insulating layer 421 may be formed by removing a portion of the first insulating material layer 1010 through an etching process.

In the process of forming the first gate insulating layer 421, an area of a portion exposed by the second etch mask, that is, an area of a portion removed by the etching process, may be smaller than an area of a portion exposed by the first etch mask in the process of forming the first gate insulating layer 421 in <case 1>.

That is, since the portion of the first insulating material layer 1010 remaining after being removed by etching is larger in <case 2> than in <case 1>, the first gate insulating layer 421 in <case 2> may cover not only the upper surface but also the side surfaces of the first semiconductor pattern 431, unlike the first gate insulating layer 421 in <case 1>.

Referring to <case 1> and <case 2> of FIG. 10B, a second semiconductor pattern 441 may be formed on the buffer layer 410 in the display area AA.

During the process of forming the second semiconductor pattern 441, an etch mask (hereinafter referred to as a third etch mask) may be used to form the second semiconductor pattern 441.

The second semiconductor pattern 441 may be formed through the process of depositing a second oxide layer (not shown) on the entire surface, applying a photoresist to the second oxide layer, and exposing and etching using a third etch mask.

The second semiconductor pattern 441 may be formed in the display area AA.

A second insulating material layer 1020 may be formed on the second semiconductor pattern 441, the first gate insulating layer 421, and the buffer layer 410. The second insulating material layer 1020 is shown as a single layer, but is not necessarily limited thereto, and may also be formed as a double layer.

The second insulating material layer 1020 may be formed in the entire area including the display area AA and the non-display area NA. In this case, due to the first gate insulating layer 421 formed in the non-display area NA, the second insulating material layer 1020 may be formed higher in the area where the first semiconductor pattern 431 is disposed.

The second insulating material layer 1020 may be made of the same material as the first insulating material layer 1010, but is not limited thereto.

The second insulating material layer 1020 may serve to insulate between the semiconductor pattern and a gate electrode of a transistor.

As described above with reference to FIGS. 6 to 10, if the first gate insulating layer 421 is disposed only on the upper surface of the first semiconductor pattern 431 in the non-display area NA, in particular, if the first semiconductor pattern 431 and the first gate insulating layer 421 are collectively deposited and then etched at once, there may be omitted the process of applying the photoresist to the first oxide layer 1000 to form the first semiconductor pattern 431, exposing and etching.

That is, the process of directly applying photoresist on the first oxide layer 1000 may be omitted, thereby preventing photoresist residue from remaining on the top of the oxide layer during the patterning process and contaminating the interface. In addition, since there is no problem of oxygen being separated from the upper interface of the oxide layer, there may not be required a separate process for oxygen compensation.

In addition, if the first gate insulating layer 421 is located only in the non-display area NA, the second semiconductor pattern 441 is no longer disposed on the first gate insulating layer 421, so that it is possible to prevent the deterioration of the second semiconductor pattern 441 due to the large amount of oxygen contained in the first gate insulating layer 421, thereby preventing a decrease in the current characteristics of the driving thin film transistor DT and the resulting luminance defects of the display device.

In addition, since the first gate insulating layer 421 is disposed only on the first semiconductor pattern 431 in the non-display area NA, that is, since the first gate insulating layer 421 is disposed only in a very local area, the conditions for forming the second gate insulating layer 422 may be almost not limited, thereby increasing the degree of freedom in the process of forming the second gate insulating layer 422.

Furthermore, if the first gate insulating layer 421 covers not only the upper surface but also the side surfaces of the first semiconductor pattern 431, it is possible to prevent the first semiconductor pattern 431 from being affected and deteriorated by a wet etching process performed when forming the second semiconductor pattern 441, thereby preventing performance degradation of the first thin film transistor GT1.

The embodiments of the present disclosure described above are briefly described as follows.

According to an embodiment of the present disclosure, there may provide a display device including a substrate including a first area and a second area, a buffer layer on the substrate, a first semiconductor pattern disposed in the first area and on the buffer layer, a second semiconductor pattern disposed in the second area and on the buffer layer, a first gate insulating layer disposed on the first semiconductor pattern in a portion of the first area, and covering at least a portion of an upper surface of the first semiconductor pattern, and a second gate insulating layer disposed on the first gate insulating layer, the second semiconductor pattern, and the buffer layer.

In the display device according to embodiments of the present disclosure, the first gate insulating layer may cover the entire of the upper surface of the first semiconductor pattern.

In the display device according to embodiments of the present disclosure, the first gate insulating layer may cover the entire of the upper surface and a side surface of the first semiconductor pattern.

In the display device according to embodiments of the present disclosure, the first semiconductor pattern and the second semiconductor pattern may be disposed on the same layer.

The display device according to embodiments of the present disclosure may further include a first gate electrode on the first semiconductor pattern, and a second gate electrode on the second semiconductor pattern. A distance between the first gate electrode and the first semiconductor pattern may be greater than a distance between the second gate electrode and the second semiconductor pattern.

In the display device according to embodiments of the present disclosure, the first gate insulating layer may be disposed in at least a partial area on the second semiconductor pattern.

The display device according to embodiments of the present disclosure may further include a first gate electrode on the first semiconductor pattern, and a second gate electrode on the second semiconductor pattern. A distance between the first gate electrode and the first semiconductor pattern may be equal to a distance between the second gate electrode and the second semiconductor pattern.

In the display device according to embodiments of the present disclosure, the first gate insulating layer may cover the entire of an upper surface and a side surface of the second semiconductor pattern.

In the display device according to embodiments of the present disclosure, at least one of the first gate insulating layer or the second gate insulating layer disposed on the second semiconductor pattern may include at least some fluorine.

In the display device according to embodiments of the present disclosure, the second gate insulating layer may have the same thickness in the first area and the second area.

In the display device according to embodiments of the present disclosure, the first semiconductor pattern may include a high-mobility oxide, and the second semiconductor pattern may include a low-mobility oxide.

In the display device according to embodiments of the present disclosure, a first area may be a non-display area and the second area may be a display area. The first semiconductor pattern and the first gate insulating layer may be located in an area where a gate driving circuit is located within the non-display area.

In the display device according to embodiments of the present disclosure, at least one of the first gate insulating layer or the second gate insulating layer may include at least some fluorine.

According to an embodiment of the present disclosure, there may provide a display device including a substrate including a first area and a second area, a first transistor disposed in the first area and including a first semiconductor pattern, a first gate electrode, a first source electrode, and a first drain electrode, a second transistor disposed in the second area and including a second semiconductor pattern, a second gate electrode, a second source electrode, and a second drain electrode, a first gate insulating layer disposed between the first gate electrode and the first semiconductor pattern in a partial area of the first area, and a second gate insulating layer disposed between the first gate insulating layer and the first gate electrode. In this case, the first gate insulating layer may overlap with the first semiconductor pattern, and the second gate insulating layer may be disposed between the second gate electrode and the second semiconductor pattern.

In the display device according to embodiments of the present disclosure, the first gate insulating layer may cover the entire of an upper surface of the first semiconductor pattern.

In the display device according to embodiments of the present disclosure, first gate insulating layer may cover the entire of an upper surface and a side surface of the first semiconductor pattern.

In the display device according to embodiments of the present disclosure, the first semiconductor pattern and the second semiconductor pattern may be disposed on the same layer.

In the display device according to embodiments of the present disclosure, a distance between the first gate electrode and the first semiconductor pattern may be greater than a distance between the second gate electrode and the second semiconductor pattern.

In the display device according to embodiments of the present disclosure, the first gate insulating layer may be disposed in at least a partial area on the second semiconductor pattern.

In the display device according to embodiments of the present disclosure, a distance between the first gate electrode and the first semiconductor pattern may be equal to a distance between the second gate electrode and the second semiconductor pattern.

In the display device according to embodiments of the present disclosure, the first gate insulating layer may cover the entire of an upper surface and a side surface of the second semiconductor pattern.

In the display device according to embodiments of the present disclosure, at least one of the first gate insulating layer or the second gate insulating layer disposed on the second semiconductor pattern may include at least some fluorine.

According to an embodiment of the present disclosure, there may provide a method of manufacturing a display device including forming a first semiconductor pattern in a first area on a substrate and forming a first gate insulating layer on at least a portion of the first semiconductor pattern, forming a second semiconductor pattern in a second area on the substrate, and forming a second gate insulating layer on the first gate insulating layer and the second semiconductor pattern.

In the method of manufacturing a display device according to embodiments of the present disclosure, step of forming a first semiconductor pattern in a first area on a substrate and forming a first gate insulating layer on at least a portion of the first semiconductor pattern may include forming a first oxide layer on the substrate and forming a first insulating material layer on the first oxide layer, and etching both the first oxide layer and the first insulating material layer using one etch mask.

In the method of manufacturing a display device according to embodiments of the present disclosure, step of forming a first semiconductor pattern in a first area on a substrate and forming a first gate insulating layer on at least a portion of the first semiconductor pattern may include forming a first oxide layer on the substrate and then etching the first oxide layer, and forming a first insulating material layer after etching the first oxide layer, and etching the first insulating material layer.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a first area and a second area;
a buffer layer on the substrate;
a first semiconductor pattern disposed in the first area and on the buffer layer;
a second semiconductor pattern disposed in the second area and on the buffer layer;
a first gate insulating layer on the first semiconductor pattern in a portion of the first area, and covering at least a portion of an upper surface of the first semiconductor pattern; and
a second gate insulating layer on the first gate insulating layer, the second semiconductor pattern, and the buffer layer.

2. The display device of claim 1, wherein the first gate insulating layer entirely covers the upper surface of the first semiconductor pattern.

3. The display device of claim 1, wherein the first gate insulating layer entirely covers the upper surface and a side surface of the first semiconductor pattern.

4. The display device of claim 1, wherein the first semiconductor pattern and the second semiconductor pattern are disposed on a same layer.

5. The display device of claim 1, further comprising:
a first gate electrode on the first semiconductor pattern; and
a second gate electrode on the second semiconductor pattern,
wherein a distance between the first gate electrode and the first semiconductor pattern is greater than a distance between the second gate electrode and the second semiconductor pattern.

6. The display device of claim 1, wherein the first gate insulating layer is disposed in at least a partial area on the second semiconductor pattern.

7. The display device of claim 6, further comprising:
a first gate electrode on the first semiconductor pattern; and
a second gate electrode on the second semiconductor pattern,
wherein a distance between the first gate electrode and the first semiconductor pattern is equal to a distance between the second gate electrode and the second semiconductor pattern.

8. The display device of claim 6, wherein the first gate insulating layer entirely covers an upper surface and a side surface of the second semiconductor pattern.

9. The display device of claim 6, wherein at least one of the first gate insulating layer or the second gate insulating layer disposed on the second semiconductor pattern includes at least some fluorine.

10. The display device of claim 1, wherein the second gate insulating layer has a same thickness in the first area and the second area.

11. The display device of claim 1, wherein the first semiconductor pattern includes a high-mobility oxide, and the second semiconductor pattern includes a low-mobility oxide.

12. The display device of claim 1, wherein a first area is a non-display area and the second area is a display area,
wherein the first semiconductor pattern and the first gate insulating layer are located in an area where a gate driving circuit is located within the non-display area.

13. The display device of claim 1, wherein at least one of the first gate insulating layer or the second gate insulating layer includes at least some fluorine.

14. The display device of claim 1, wherein the first gate insulating layer includes a triple layer or a double layer, at least one layer of which includes fluorine.

15. A display device, comprising:
a substrate including a first area and a second area;
a first transistor disposed in the first area and including a first semiconductor pattern, a first gate electrode, a first source electrode, and a first drain electrode;
a second transistor disposed in the second area and including a second semiconductor pattern, a second gate electrode, a second source electrode, and a second drain electrode;
a first gate insulating layer disposed between the first gate electrode and the first semiconductor pattern in a partial area of the first area; and
a second gate insulating layer disposed between the first gate insulating layer and the first gate electrode,
wherein the first gate insulating layer overlaps with the first semiconductor pattern, and
wherein the second gate insulating layer is disposed between the second gate electrode and the second semiconductor pattern.

16. The display device of claim 15, wherein the first gate insulating layer entirely covers an upper surface of the first semiconductor pattern.

17. The display device of claim 15, wherein the first gate insulating layer entirely covers an upper surface and a side surface of the first semiconductor pattern.

18. The display device of claim 15, wherein the first semiconductor pattern and the second semiconductor pattern are disposed on a same layer.

19. The display device of claim 15, wherein a distance between the first gate electrode and the first semiconductor pattern is greater than a distance between the second gate electrode and the second semiconductor pattern.

20. The display device of claim 15, wherein the first gate insulating layer is disposed in at least a partial area on the second semiconductor pattern.

21. The display device of claim 20, wherein a distance between the first gate electrode and the first semiconductor pattern is equal to a distance between the second gate electrode and the second semiconductor pattern.

22. The display device of claim 20, wherein the first gate insulating layer entirely covers an upper surface and a side surface of the second semiconductor pattern.

23. The display device of claim 20, wherein at least one of the first gate insulating layer or the second gate insulating layer disposed on the second semiconductor pattern includes at least some fluorine.

24. A method of manufacturing a display device, comprising:
forming a first semiconductor pattern in a first area on a substrate and forming a first gate insulating layer on at least a portion of the first semiconductor pattern;
forming a second semiconductor pattern in a second area on the substrate; and
forming a second gate insulating layer on the first gate insulating layer and the second semiconductor pattern.

25. The method of claim 24, wherein forming a first semiconductor pattern in a first area on a substrate and forming a first gate insulating layer on at least a portion of the first semiconductor pattern comprises:
forming a first oxide layer on the substrate and forming a first insulating material layer on the first oxide layer; and
etching both the first oxide layer and the first insulating material layer using one etch mask.

26. The method of claim 24, wherein forming a first semiconductor pattern in a first area on a substrate and forming a first gate insulating layer on at least a portion of the first semiconductor pattern comprises:
forming a first oxide layer on the substrate;
etching the first oxide layer;
forming a first insulating material layer after etching the first oxide layer; and
etching the first insulating material layer.
